(19) United States
(12) Patent Application Publication
(10) Pub. No.: US 2012/0263927 A1
(43) Pub. Date: Oct. 18, 2012

(54) METHOD FOR APPLYING A POWDER COATING TO A NON-CONDUCTIVE WORK PIECE

(76) Inventors: Theodore F. Stranczek, Highland Village, TX (US); J.F. Van Gilder, Rockport, TX (US)

(21) Appl. No.: 13/445,867

(22) Filed: Apr. 12, 2012

Related U.S. Application Data
(60) Provisional application No. 61/517,026, filed on Apr. 12, 2011.

(51) Int. Cl. B05D 1/12; C23C 14/35; B32B 5/16; B05D 3/06

(52) U.S. Cl. 428/206; 427/180; 427/597; 204/192.15

(57) ABSTRACT

This invention relates to a method whereby a metalized coating is applied to the surface of composite, carbon fiber, syntactic foam, polymer foam or other non-conductive material in a vacuum chamber utilizing a Physical Vapor Deposition (PVD) processes. There are at least three coating methodologies which may be employed to achieve the desired metallic surface characteristics. Through the application of any of the three coating processes, the metallically coated substrate, work piece, will become electrostatically charged. Once applied, this coating will facilitate the next process which entails the application of electrically charged powder coat products (more commonly referred to as Powder Coating) to the surface of the metalized composite substrate. The resulting finish enhances the composite substrate enabling its use in a myriad of new applications and processes.

### CROSS-REFERENCE TO RELATED APPLICATIONS

Provisional Application Ser. No. 61/517,026 Apr. 12, 2011

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### BACKGROUND OF THE INVENTION

1. Field of the Invention

This invention details a system and methodology whereby a metalized coating is applied to the surface of composite, carbon fiber, syntactic foam, polymer foam or other non-conductive materials in a vacuum chamber utilizing a Physical Vapor Deposition (PVD) processes. Once applied, this coating will enable the substrate to hold an electrostatic charge thereby facilitating the next process which entails the application of metalized and electrically charged powder coat products, commonly and hereinafter referred to as Powder Coating, to the surface of the metalized composite substrate. The resulting finish enhances the composite substrate enabling its use in a myriad of new applications and processes

2. Description of Related Art

Composite, syntactic foam, polymer foam and carbon fiber materials have been used to construct primary and secondary structures for a myriad of products utilized in the aerospace, marine, recreational vehicle and entertainment industries. These composite substrates possess many desirable characteristics in that they are light weight and can be vacuum formed into complex forms and shapes.

Presently, vacuum formed composite structures require extensive post forming preparation. In the majority of cases, a primer-filler is added to the substrate after the part is cured in an oven to create a smooth surface prior to application of exterior finishes. The man hours required to prepare these surfaces is very time consuming and expensive. The type and variety of surface finishes is limited to ordinary paint, cloth or leather fabrics, requiring the use of toxic adhesives and labor intensive finishing and installation man hours.

The present invention applies a powder coating to the surface of these substrates, in lieu of currently accepted surface finishes opening up a world of new surface colors, applications and finishes. At the time of the present invention, there is no one in the previously mentioned industries applying Powder Coating to composite based substrates.

Presently, there is no documented method by which composite structures can accept an application of powder coating. In order for powder coating to adhere to a composite substrate it must be capable of holding an electrostatic charge and withstand temperatures approaching 450° F. for up to thirty (30) minutes. No currently manufactured composite substrate can hold an electrostatic charge without further enhancement to its physical structure.

### BRIEF SUMMARY OF THE INVENTION

The ability to greatly enhance the finish and durability of composite materials beyond the application of paints and fabrics has been the goal of numerous aerospace manufacturers, aircraft, marine and recreational vehicle completion centers and selected consumer orientated companies.

Composite materials manufactured from woven adhesive prepreg and carbon fiber elements are widely used in the manufacture of interior panels, furniture and sub-structure in the marine and aircraft modification business. To expand the range of surface finishes and extend their durability without the costly addition of fillers and labor man hours, in addition to reducing the final product's weight is what modification managers are seeking today.

Composite substrates are by their very nature non-conductive materials incapable of retaining an electrostatic charge. This restriction virtually eliminates any opportunity to Powder Coat these materials. On the other hand, if composite materials could be Powder Coated, over 1000 new surface finishes are available to the manufacturer or modification center.

By coating a composite substrate, a work piece, with a metallic surface without damaging or altering its base molecular composition would greatly enhance the utilization and application possibilities of this material. Such a coating operation must be performed in a vacuum chamber operating at a specified vacuum setting.

Coating in a vacuum chamber entails vaporizing specific materials under high vacuum and thru electromagnetic and molecular acceleration, attaching the vaporized molecules to the surface of the target substrate. Careful control of varying coating parameters within the chamber enables the molecules of vaporized metal to coat various substrates at very low temperatures. This is accomplished by electronically controlling the rate of metal deposition to attain the desired coating thicknesses. Careful attention is also necessary to properly match the type of coating material to the substrate to obtain the proper coating coverage and desired surface characteristics.

Attributes of the present invention:
Facilitates the application of new and unique surface coatings.
Introduces over 1000 new types of decorative, natural and avant-garde finishes
Superior adhesion and durability
High density, hardness and strength
Value added coatings at affordable prices
Great product differentiator
Produces high-end finishes
Improved surface wear resistance
Eliminates cost and weight barriers
Cosmetically appealing substitute for current standard materials
Environmentally “green” technology
Adds an elegant natural look with life extending durability

Coating the dynamic surface of a substrate includes the following steps:
Pre-conditioning of the dynamic surface of the article
Inserting the article into a vacuum chamber
Evacuating the chamber to a predetermined vacuum
Ion conditioning the dynamic surface of the article
Depositing an interface layer on the surface
Depositing a specific coating on the interface layer
Depositing a protective coating on the coating layer
Evacuate the chamber and recover the article

These and other objects, advantages and features of this invention will be apparent from the following description taken with reference to the accompanying drawings, wherein is shown a preferred embodiment of the invention.

### BRIEF DESCRIPTION OF THE SEVERAL VIEWS OF THE DRAWINGS

FIG. 1: is a typical vacuum chamber

FIG. 2: Shows depositing material onto a substrate in a vacuum chamber according to the present invention.

FIG. 3: Chamber Coating Devices, Tooling and Article to be Coated

FIG. 4: Magnetron Sputtering Process

FIG. 5: E-Beam Evaporation Process

FIG. 6: Beam Assisted E-Beam Evaporation Process

### DETAILED DESCRIPTION OF THE INVENTION

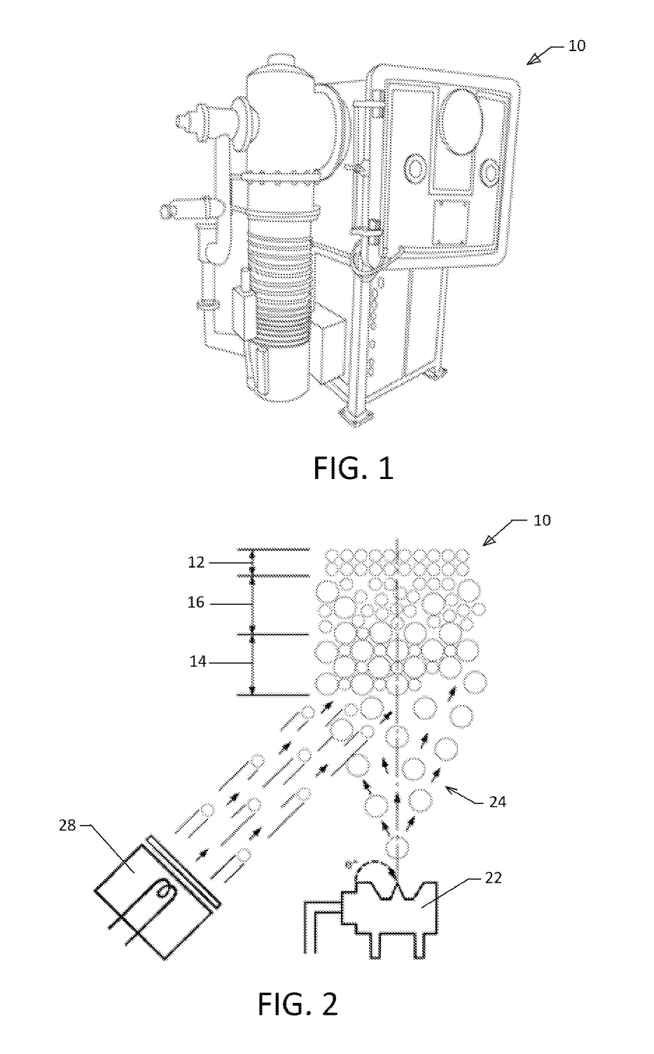

Referring now to the drawing and in particular to FIG. 1 and FIG. 2, a vacuum chamber is referred to by reference numeral 10. Vacuum chamber 10 is used for coating a composite substrate, a work piece, 12 with a metallic surface 14 without damaging or altering its base molecular composition will greatly enhance the utilization and application possibilities of this material. Applying metallic surface 14 also creates a mixed layer 16 of substrate and metallic material, so that metallic surface strongly adheres to the composite substrate. Once applied, coating 14 will enable the substrate to hold an electrostatic charge. There are three (3) coating methodologies, known in the art, which may be employed (depending on the desired coating results) to achieve the desired surface characteristics. They will be described below.

The present invention requires the following manufacturing processes to be incorporated specifically as described herein.

Process #1: Construction and Curing of the Composite Material.
NOTE: There are numerous manufacturers of woven adhesive prepreg composite materials. As an example, woven adhesive prepreg (L-501) manufactured by J D Lincoln will be used to illustrate the process. Equivalent woven prepreg materials from other manufacturers may be substituted provided the manufacturing processes are strictly adhered too and the materials can sustain the required temperature tolerances.
   Initial processing of the composite woven adhesive prepreg L-501:
1. The woven prepreg is evenly constructed in single or multiple layers depending on the product structure requirements.
2. The structure can be cured with a vacuum bag, press or autoclave type cures from 90 minutes at 235° F. (113° C.) or in just 40 minutes at 275° F. (235° C.) with contact pressure 235° F. (113° C.) cure temperatures.
3. Remove the structure from the oven and allow 24 hours before processing.
4. Optional: Application of a Primer-filler to the cured composite substrate:
   NOTE: If a very smooth surface is required, adding a primer-filler is recommended. For this exercise DuPont ChromaSurfacer® 7704S Urethane primer filler is used. Equivalent primer fillers may be substituted provided temperature tolerances and finishing procedures are strictly adhered too.
      i. Clean surface thoroughly with mild detergent and water.
      ii. Wipe surface with manufacturers recommended cleaner (DuPont Plas-Stick® 2320S).
      iii. Sand and featheredge substrate with P180 followed by P240 grit paper.
      iv. Remove sanding sludge with manufactures recommended cleaner (DuPont Final Klean™ 3901S).
      v. Apply even layers of DuPont ChromaSurfacer® 7704S per manufactures recommendations. Three (3) coats are recommended. Dry thoroughly before applying consecutive coats.
         1. Air Dry
         a. 7 to 10 minutes
         b. Wet sanding 2 hours
         c. Dry sanding 2 hours
         2. Allow primer to dry overnight
         3. Clean Surface with manufactures recommended surface cleaner or (Sontara PS-39X55) before applying sealer or top coat.
         4. Allow sealer and/or top coat to dry overnight

Process #2: Coating the Substrate in a Vacuum Chamber:

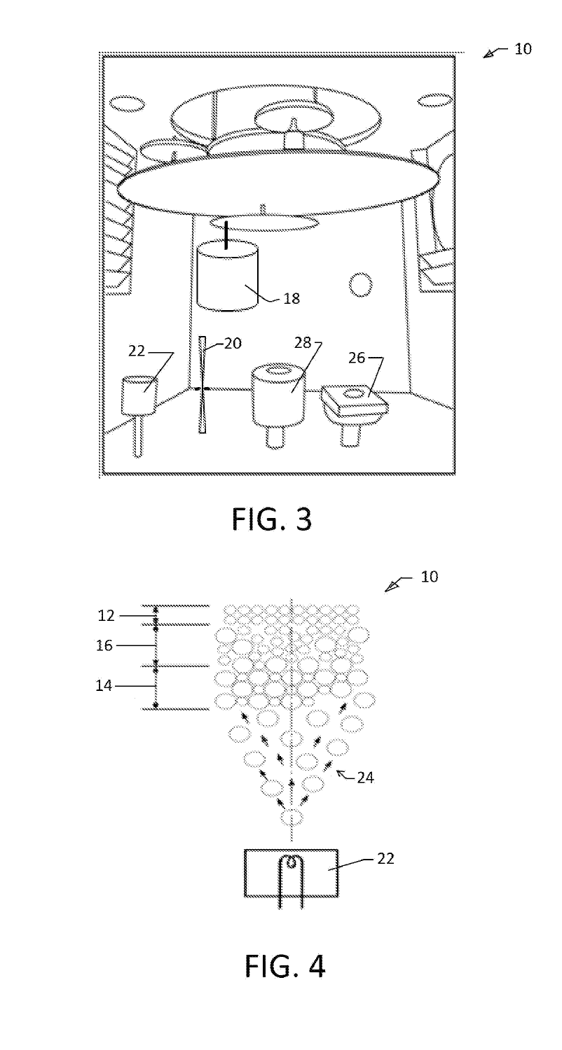

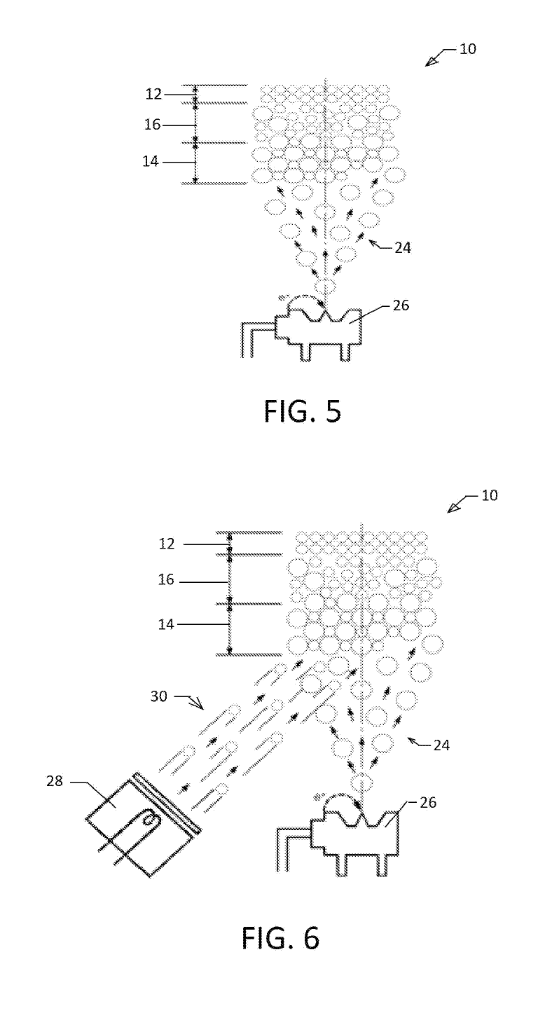

Referring to FIG. 3,
1. Clean, properly position and load the substrate (article 18) to be coated into the vacuum chamber.
2. Determine proper coating material to achieve desired article (substrate) surface properties enabling it to retain an electrostatic charge.
3. Position the deposition monitor 20 in correct location for coating
4. Evacuate vacuum chamber to the predetermined vacuum
5. Utilizing one of the following methods apply the desired coating to the article (substrate):
   a. Magnetron Sputtering Process
      Referring to FIG. 4,
         i. Inject proper gas(s) at preset rate into the chamber
         ii. Apply power to the magnetron 22 thereby sputtering the coating material and creating a plasma cloud 24
         iii. With the article immersed in the cloud, coating begins
         iv. Continue coating until the predetermined thickness is achieved
         v. Vent the chamber and recover the article
   b. E-Beam Evaporation Process
      Referring to FIG. 5,
         i. Program deposition monitor 20 to achieve the desired deposition rate and coating thickness
         ii. Turn on high voltage to the E-Gun evaporating the desired coating material on to the article (substrate)
         iii. Continue coating until the predetermined thickness is achieved
         iv. Vent the chamber and recover the article
   c. Ion Beam Assisted E-Beam Deposition Process
      Referring again to FIG. 2,
         i. Program deposition monitor 20 to achieve the desired deposition rate and coating thickness
         ii. Inject proper gas at preset rate into the chamber
         iii. Turn on RF Power to ion mill 28
         iv. Turn on high voltage to the E-Gun 26 evaporating the coating material on to article 18 (substrate) while the molecules are given additional velocity with the help of the ion mill
         v. Continue coating until the predetermined thickness is achieved
         vi. Vent the chamber and recover the article
6. Carefully check each product to confirm its ability to hold an electrostatic charge.

By coating a composite substrate with a metallic surface without damaging or altering its base molecular composition will greatly enhance the utilization and application possibilities of this material. Once applied, this coating will enable the substrate to hold an electrostatic charge. Such a coating operation must be performed in a vacuum chamber (See FIG. 1) operating at a specified vacuum.

Coating in a vacuum chamber entails vaporizing specific materials under high vacuum and thru electromagnetic and molecular acceleration, attaching the vaporized molecules to the surface of the target substrate. (See FIG. 2) Careful control of varying coating parameters within the chamber enables the molecules of vaporized metal to coat various substrates at very low temperatures. This is accomplished by electronically controlling the rate of metal deposition to attain the desired coating thicknesses. Careful attention is also necessary to properly match the type of coating material to the substrate to obtain the proper coating coverage and desired surface characteristics.

Process #3: Applying the Desired Powder Coat Finish:

Once the substrate has received the desired metallic coating to enable it to hold an electrostatic charge, the article is sent on to be Powder Coated. Powder Coating is a commercially available process and therefore will not be described in any great detail.

Powder Coating is an advanced method of applying a decorative and protective finish to a wide variety of materials and products.

The Powder Coating process uses a solvent free dry mix of plastic resins, pigments and fillers that melt and fuse together when heated (375° F. to 450° F.). The solid particles of coating are electrostatically charged in a spray gun and carried by low velocity to the surface of the article to be coated.

The electrostatic charge holds the powder particles in place while the paint is cured in an oven at the required temperature. The heat from the oven causes a chemical reaction to occur and the powder to cure, creating a highly durable finish.

Any object that can hold an electrostatic charge and withstand the heat of the curing process can be powder coated. Powder coating can be applied to intricate surfaces and still maintain a uniform finish across the entire article. Until now, only metal objects could be powder coated.

With the advent of the present invention, numerous composite and non-metallic materials may now be modified to accept the powder coating process.

From the foregoing it will be seen that this invention is well adapted to attain all of the ends and objectives hereinabove set forth, together with other advantages which are inherent to the apparatus.

It will be understood that certain features and subcombinations are of utility and may be employed without reference to other features and subcombinations. This is contemplated by and is within the scope of the claims.

As many possible embodiments may be made of the invention without departing from the scope thereof, it is to be understood that all matter herein set forth or shown in the figures of the accompanying drawings is to be interpreted as illustrative and not in a limiting sense.

1. A process for powder coating a non-metallic non-electrically conducting work piece, comprising the steps of:
applying a metal deposition over the parts of the work piece to be powder coated; and
powder coating the work piece with the metallic coating in the same manner as powder coating a metal object.

2. A process according to claim 1, wherein the step of applying a metal deposition over the parts of the work piece to be powder coated comprises coating the work piece in a vacuum chamber.

3. A process according to claim 2, wherein the step of coating the work piece in a vacuum chamber comprises coating the work piece using a magnetron sputtering process.

4. A process according to claim 2, wherein the step of coating the work piece in a vacuum chamber comprises coating the work piece using an E-beam evaporation process.

5. A process according to claim 2, wherein the step of coating the work piece in a vacuum chamber comprises coating the work piece using an ion beam assisted E-beam deposition process.

6. A process according to claim 1 wherein the non-metallic non-electrically conducting work piece comprises a composite material.

7. A process according to claim 6, wherein the step of applying a metal deposition over the parts of the work piece to be powder coated comprises coating the work piece in a vacuum chamber.

8. A process according to claim 7, wherein the step of coating the work piece in a vacuum chamber comprises coating the work piece using a magnetron sputtering process.

9. A process according to claim 7, wherein the step of coating the work piece in a vacuum chamber comprises coating the work piece using an E-beam evaporation process.

10. A process according to claim 7, wherein the step of coating the work piece in a vacuum chamber comprises coating the work piece using an ion beam assisted E-beam deposition process.

11. A non-metallic non-electrically conducting work piece at least partially covered with a powder coating prepared by a process comprising the steps of:
applying a metal deposition over the parts of the work piece to be powder coated; and
powder coating the work piece with the metallic coating in the same manner as powder coating a metal object.

12. A non-metallic non-electrically conducting work piece according to claim 11, wherein the step of applying a metal deposition over the parts of the work piece to be powder coated comprises coating the work piece in a vacuum chamber.

13. A non-metallic non-electrically conducting work piece according to claim 12, wherein the step of coating the work piece in a vacuum chamber comprises coating the work piece using a magnetron sputtering process.

14. A non-metallic non-electrically conducting work piece according to claim 12, wherein the step of coating the work piece in a vacuum chamber comprises coating the work piece using an E-beam evaporation process.

15. A non-metallic non-electrically conducting work piece according to claim 12, wherein the step of coating the work piece in a vacuum chamber comprises coating the work piece using an ion beam assisted E-beam deposition process.

16. A non-metallic non-electrically conducting work piece according to claim 11 wherein the non-metallic non-electrically conducting work piece comprises a composite material.

17. A non-metallic non-electrically conducting work piece according to claim 16, wherein the step of applying a metal deposition over the parts of the work piece to be powder coated comprises coating the work piece in a vacuum chamber.

18. A non-metallic non-electrically conducting work piece according to claim 17, wherein the step of coating the work piece in a vacuum chamber comprises coating the work piece using a magnetron sputtering process.

19. A non-metallic non-electrically conducting work piece according to claim 17, wherein the step of coating the work piece in a vacuum chamber comprises coating the work piece using an E-beam evaporation process.

20. A non-metallic non-electrically conducting work piece according to claim 17, wherein the step of coating the work piece in a vacuum chamber comprises coating the work piece using an ion beam assisted E-beam deposition process.
